(19) United States
(12) Patent Application Publication
(10) Pub. No.: US 2023/0142868 A1
(43) Pub. Date: May 11, 2023

(54) MONITORING WAFER AND MONITORING SYSTEM

(71) Applicant: CHANGXIN MEMORY TECHNOLOGIES, INC., Hefei City, Anhui (CN)

(72) Inventor: Xiao Wu, Hefei City, Anhui (CN)

(21) Appl. No.: 17/433,305

(22) PCT Filed: Mar. 1, 2021
(86) PCT No.: PCT/CN2021/078511

§ 371 Date: Aug. 24, 2021

(30) Foreign Application Priority Data
Apr. 2, 2020 (CN) 202010254958.9

(51) Int. Cl. H01L 21/66; H01L 21/67; H02J 50/10

(52) U.S. Cl. CPC H01L 22/34; H01L 21/67253; H02J 50/10; H01L 21/67288; H01L 21/67276

(57) ABSTRACT

Embodiments of the present application provide a monitoring wafer and a monitoring system. The monitoring wafer comprises a substrate, the substrate having a first surface that is configured to face a wafer carrier and fixed to the wafer carrier; and a pressure detection device, located on the substrate and configured to obtain pressure on the first surface.

### CROSS-REFERENCE TO RELATED APPLICATIONS

The present application claims the priority to Chinese Patent Application No. 202010254958.9, titled “Monitoring wafer and monitoring system”, filed on Apr. 2, 2020, which is incorporated herein by reference in its entirety.

### TECHNICAL FIELD

The present application relates to the field of semiconductors, and in particular, to monitoring wafer and monitoring system.

### BACKGROUND

At present, the electrostatic chuck is an important part of a semiconductor etching machine. When a semiconductor etching machine is used to assist the manufacturing process of a wafer, the wafer is usually carried by an electrostatic chuck for the purpose of fixing the wafer. In addition, in order to speed up the production efficiency, a same manufacturing process is usually performed in multiple chambers of a machine.

At the end of the manufacturing process, if the products formed in different chambers behave differently, it is necessary to check whether a fault occurs in the semiconductor etching machine. In addition, if helium leakage occurs in the reaction chambers during the manufacturing process, it is also necessary to check whether a fault occurs in the semiconductor etching machine.

When checking the semiconductor etching machine, it is necessary to replace the structure that may be faulty. However, due to the difficult assembly and high price of the electrostatic chuck, it may be time-consuming, labor-intensive and costly if the structure is replaced with a new one when the electrostatic chuck has no performance problems.

### SUMMARY

Some embodiments of the present application provide a monitoring wafer and a monitoring system. The monitoring wafer can detect pressure on a surface of the monitoring wafer facing the wafer carrier, and then, based on the detected pressure data, make a determination as to whether there is any problem with the carrying performance of the wafer carrier.

In order to solve the above problem, some embodiments of the present application provide a monitoring wafer, comprising: a substrate, the substrate having a first surface that is configured to face a wafer carrier and fixed to the wafer carrier; and a pressure detection device, located on the substrate and configured to obtain pressure on the first surface.

In addition, the substrate has a second surface opposite to the first surface, the substrate has a groove extending from the second surface to the first surface, and the pressure detection device is embedded in the groove; and the monitoring wafer further comprises a protective layer located on the second surface and configured to seal the pressure detection device.

In addition, the monitoring wafer further comprises: an adhesive layer configured to adhere the substrate and the protective layer, a material for the adhesive layer comprising silicone resin adhesive.

In addition, the monitoring wafer further comprises: an induction coil, connected to the pressure detection device and configured to supply power to the pressure detection device.

In addition, the monitoring wafer further comprises: a power supply device, connected to the pressure detection device and the induction coil, respectively, and configured to receive charging of the induction coil and to supply power to the pressure detection device.

In addition, the monitoring wafer further comprises: a processor connected to the pressure detection device and configured to store pressure data obtained by the pressure detection device.

In addition, the processor is further configured to send the stored pressure data through the induction coil.

In addition, the pressure detection device comprises a signal amplifier and at least one pressure sensor, and the signal amplifier is configured to amplify the pressure obtained by the pressure sensor.

In addition, in a direction in which the pressure sensor faces the first surface, the distance between a surface of the pressure sensor facing the first surface and the first surface is greater than or equal to 0.2 mm.

In addition, the pressure detection device comprises a plurality of pressure sensors; the first surface comprises a middle region and a peripheral region surrounding the middle region; and the middle region comprises at least one pressure sensor and the peripheral region comprises at least one pressure sensor.

In addition, in a direction in which the middle region faces the peripheral region, the peripheral region comprises a plurality of ring-shaped sub-regions sequentially surrounding one another, and each of the ring-shaped sub-regions comprises at least one pressure sensor.

In addition, the first surface is a round surface and the number of pressure sensors is 33.

Some embodiments of the present application further provide a monitoring system, comprising: at least one monitoring wafer described above; a wafer transfer box, configured to carry the monitoring wafer and obtain pressure data in the monitoring wafer; and an electronic device, connected to the wafer transfer box and configured to obtain and analyze the pressure data.

In addition, the monitoring wafer comprises an induction coil and a power supply device connected to the induction coil; the wafer transfer box comprises an adapter coil and mutual inductance is possible between the induction coil and the adapter coil; and the wafer transfer box charges the power supply device in the monitoring wafer through the adapter coil and the induction coil.

Compared with the prior art, the technical solutions in some embodiments of the present application have the following advantages:

In the technical solutions, the pressure detection device detects pressure on the first surface of the substrate facing the wafer carrier. After carrying the monitoring wafer by the wafer carrier, the carrying performance of the wafer carrier may be analyzed based on the pressure data obtained by the pressure detection device.

In addition, the pressure detection device is embedded in the groove in the substrate, and is then sealed by the protective layer located on the second surface. This is helpful to avoid damage to the pressure detection device, thereby ensuring the validity of the detected pressure data.

In addition, the first surface comprises an inner region and an outer region, and the inner region or the outer region comprises at least one pressure sensor. In this way, when a fault occurs in the wafer carrier, the faulty region can be analyzed based on the pressure data detected by the pressure sensors at different positions.

### BRIEF DESCRIPTION OF THE DRAWINGS

One or more embodiments will be exemplified by pictures in the corresponding drawings. These exemplified descriptions do not constitute any limitation to the embodiments. Elements with the same reference numerals in the drawings are represented as similar. Unless otherwise stated, the drawings are not necessarily drawn to scale.

FIG. 1 is a schematic cross-sectional view of a monitoring wafer according to an embodiment of the present application;

FIGS. 2 to 4 are schematic structure diagrams of the monitoring wafer according to an embodiment of the present application;

FIG. 5 is a schematic view of the distribution of the pressure detection device according to an embodiment of the present application;

FIG. 6 is a schematic view of the change in pressure of the monitoring wafer according to an embodiment of the present application;

FIG. 7 is a schematic view of the distribution of pressure of the monitoring wafer according to an embodiment of the present application;

FIG. 8 is a schematic view of the distribution of pressure of the monitoring wafer according to another embodiment of the present application; and

FIG. 9 shows a monitoring system according to another embodiment of the present application.

### DETAILED DESCRIPTION

It may be known from the description in the background that, at present, after a product or manufacturing process goes wrong, it is impossible to determine whether there is a problem with the carrying performance of the wafer carrier without removing the wafer carrier.

In order to solve the above problem, embodiments of the present application provide a monitoring wafer, a fault location method, and a monitoring system. The pressure detection device is provided on the substrate of the monitoring wafer to detect pressure on the first surface of the substrate facing the wafer carrier. In this way, at the end of a corresponding manufacturing process, if it is found that the obtained product does not meet the requirements or there is an unexpected process deviation during the manufacturing process, a determination may be made as to whether the carrying performance of the wafer carrier is qualified based on the pressure data detected by the pressure detection device.

To make the objectives, technical solutions and advantages of the embodiments of the present application clearer, the embodiments of the present application will be further described below in detail with reference to the accompanying drawings. However, it may be understood by a person of ordinary skill in the art that, in the embodiments of the present application, many technical details are provided for the better understanding of the present application. However, the technical solutions sought to be protected by the present application can be implemented, even without these technical details and various changes and modifications based on the following embodiments.

FIG. 1 is a schematic cross-sectional view of a monitoring wafer according to an embodiment of the present application.

Referring to FIG. 1, the wafer carrier 2 carries a monitoring wafer 1, and the monitoring wafer 1 has a first surface 111 that faces the wafer carrier 2 and is fixed to the wafer carrier 2.

In this embodiment, the wafer carrier 2 is connected to a negative electrode 21 of a high-voltage power source 20. The wafer carrier 2 comprises a dielectric layer 23, and the dielectric layer 23 has a direct current electrode (DC electrode) 231 therein. When the DC electrode 231 is connected to the negative electrode 21 of the high-voltage power source 20, polarized charges will be generated on the surface of the dielectric layer 23, and the polarized charges will generate an electric field. This electric field will further facilitate the generation of polarized charges on the surface of the monitoring wafer 1 placed on the wafer carrier 2. The charges distributed on the first surface 111 are opposite in polarity to the charges distributed on the surface of the dielectric layer 23 close to the monitoring wafer 1. In this way, the wafer carrier 2 adsorbs and fixes the monitoring wafer 1.

In this embodiment, the wafer carrier 2 is also connected to a current transformer 22 in the high-voltage power source 20. The current transformer 22 is configured to detect the parameters of the current 24 generated by the charge migration in the monitoring wafer 1. The high-voltage power source 20 may adjust the output current according to the current parameters detected by the current transformer 22, and thus adjust the adsorption capacity of the wafer carrier 2.

The capacity of the wafer carrier 2 to adsorb the monitoring wafer 1 is related to the cleanliness of the first surface 111 of the monitoring wafer 1. When there are polymers adhered to the first surface 111, the adsorption capacity of the wafer carrier 2 is likely to be insufficient. As a result, it is unable to ensure the position accuracy of the monitoring wafer 1 and also unable to form products that meet the preset requirements It should be noted that the size of the monitoring wafer 1 should be the same as the size of the wafer used in the actual process. In this way, it is helpful to ensure the validity of the pressure data obtained by the monitoring wafer 1.

In this embodiment, the high-voltage power source 20 is a direct current power source (DC power source). In other embodiments, the power source is a low-current DC power source, and the positive electrode of the power source is connected to the DC electrode in the dielectric layer.

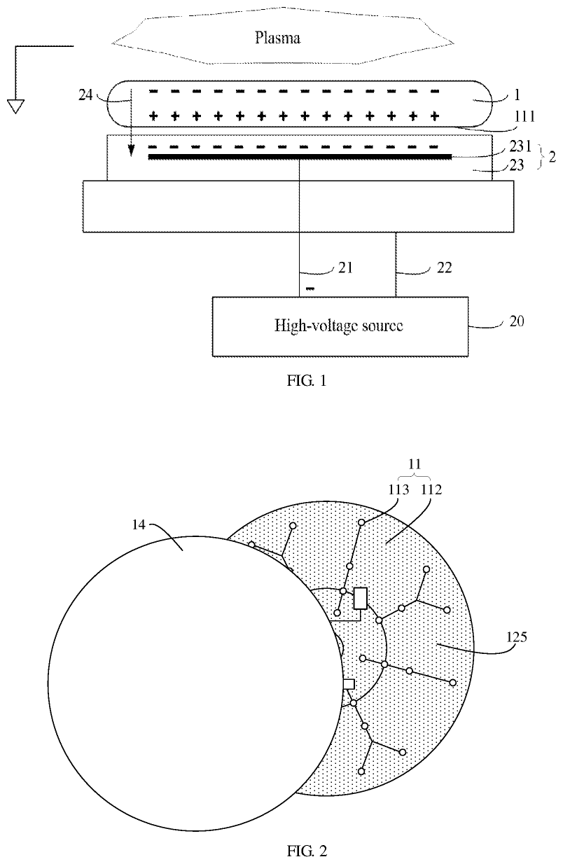

FIGS. 2 to 4 are schematic structure diagrams of the monitoring wafer according to an embodiment of the present application.

Referring to FIG. 2, the substrate 11 has a second surface 112 opposite to the first surface. The substrate 11 has a groove 113 extending from the second surface 112 to the first surface. The pressure detection device is embedded in the groove 113. The monitoring wafer 1 further comprises a protective layer 14 configured to seal the pressure detection device to avoid damage to the pressure detection device due to the manufacturing process, so as to ensure that the pressure detection device has good detection accuracy.

In this embodiment, material for the protective layer 14 comprises yttrium oxide or yttrium oxyfluoride, which is used to prevent the pressure detection device from being damaged by the plasma generated by the manufacturing process or the externally injected plasma. In addition, the monitoring wafer further comprises an adhesive layer 125 coated on the surface of the substrate 11, which is configured to adhere the substrate 11 and the protective layer 14. Material for the adhesive layer 125 comprises silicone resin adhesive which can provide good adhesion effect after solidification.

The silicone resin adhesive is obtained by mixing silicone resin (for example polymethylphenylsiloxane) with certain inorganic fillers (mica, asbestos, etc.) and organic solvents (for example toluene, xylene). The silicone resin adhesive has the properties of high temperature resistance, corrosion resistance, radiation resistance and weather resistance, and can work for a long period of time at a high temperature of 400° C. without being damaged. In this way, it is able to avoid the failure of the adhesive layer 125 caused by the high temperature in the manufacturing process, thereby ensuring the tightness of the pressure detection device and the detection accuracy of the pressure detection device.

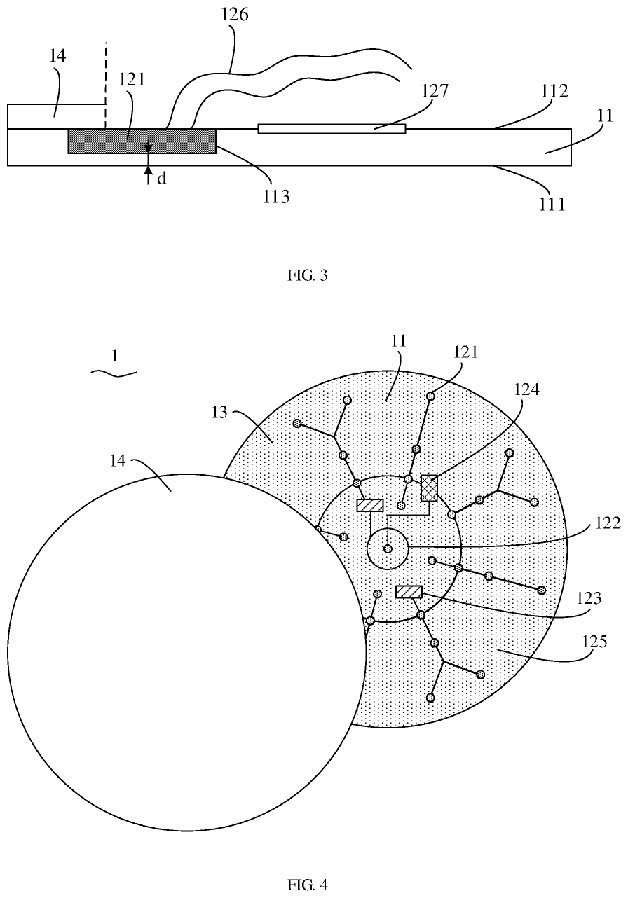

Referring to FIG. 3, the pressure detection device is embedded in the groove 113.

In this embodiment, the pressure detection device comprises a pressure sensor 121 configured to detect the pressure of its own orthographic projection on the first surface 111.

The depth of the groove 113 is usually greater than or equal to the thickness of the pressure sensor 121, so that the pressure sensor 121 can be completely embedded in the groove 113. This avoids the problem that the protective layer 14 on the second surface 112 cannot completely seal the pressure sensor 121, thereby ensuring the security of the pressure sensor 121. It should be noted that the thickness of the pressure sensor 121 may be greater than the depth of the groove 113, as long as the sealing effect of the protective layer 14 is not affected.

The detection accuracy of the pressure sensor 121 is related to the sensing distance d. The sensing distance d refers to the distance between the surface of the pressure sensor 121 facing the first surface 111 and the first surface 111 in a direction in which the pressure sensor 121 faces the first surface 111. The smaller the sensing distance d is, the higher the detection accuracy of the pressure sensor 121 is.

In this embodiment, the pressure detection device further comprises a signal amplifier (not shown) configured to amplify the pressure obtained by the pressure sensor 121, in order to improve the detection accuracy of the pressure sensor 121. In this way, it is helpful to increase the selectable range of the sensing distance d. This avoids the problem that the substrate 11 at the bottom of the groove 113 breaks because of too small thickness caused by the too small sensing distance d.

In this embodiment, the sensing distance d is greater than or equal to 0.2 mm, and the thickness of the substrate 11 is 0.8 mm to 1.2 mm, for example 0.9 mm, 1 mm, or 1.1 mm.

In addition, the monitoring wafer 1 comprises a wire 126 and a bonding pad 127. The wire 126 is used to connect the pressure sensor 121 with other electronic components. The bonding pad 127 is used to fix the wire 126 to prevent the wire 126 from moving and causing a short circuit. The bonding disk 127 and the wire 126 may be located in the groove 113 or on the second surface 112, as long as the sealing effect of the protective layer 14 is not affected.

Referring to FIG. 4, in this embodiment, the monitoring wafer 1 further comprises an induction coil 122 connected to the pressure sensor 121. The induction coil 122 can receive energy and signals transmitted by another coil that is adapted thereto, and is used to supply power to the pressure sensor 121. In this way, the monitoring wafer 1 does not need to obtain power from an external power source in a wired manner. This is helpful to avoid short-circuit or open-circuit problems that may easily occur when the wire is exposed to the process environment, thereby ensuring that the pressure sensor 121 can detect the pressure on the first surface (not shown) stably and effectively.

The monitoring wafer 1 further comprises a power supply device 123 respectively connected to the pressure sensor 121 and the induction coil 122. The power supply device 123 is configured to receive charging of the induction coil 122 and to supply power to the pressure sensor 121. In this way, there is no need to continuously supply power to the monitoring wafer 1 during the manufacturing process. The power supply device 123 needs to be charged only before the manufacturing process. This is helpful to avoid the energy transfer from being affected by the process environment or affecting the process environment, thereby ensuring that the pressure detection can be carried out stably and the preparation process can be carried out according to preset parameters.

The power supply device 123 comprises a rechargeable battery, and the number of the power supply device 123 is determined according to the power of the power supply device 123 and the power and layout of the object to which power is supplied. It should be noted that, since the current obtained by the induction coil 122 is alternating current, a frequency converter is required in the power supply device 123. The frequency converter converts the AC power received by the induction coil 122 into DC power, and then charges the power supply device 123.

The monitoring wafer 1 further comprises a processor 124 connected to the pressure sensor 121 to store pressure data obtained by the pressure sensor 121. In addition, the processor 124 is further configured to send pressure data to the outside through the induction coil 122 or Bluetooth. The way the processor 124 sends the pressure data may be actively sending in real time, actively sending according to a preset time interval or at a preset point of time, or passively sending the stored data upon receiving a preset instruction. When the processor 124 transmits signals through the induction coil 122, the frequency converter may convert the DC power from the battery into AC power and send a signal to the outside through the induction coil.

In this embodiment, the induction coil 122, the power supply device 123, and the processor 124 are all embedded in the groove 113 to ensure the tightness of the protective layer 14.

FIG. 5 is a schematic view of the distribution of the pressure detection device according to an embodiment of the present application.

In this embodiment, the pressure detection device comprises a plurality of pressure sensors 121. The first surface 111 comprises a middle region 131 and a peripheral region 132 surrounding the middle region 131. The middle region 131 comprises at least one pressure sensor 121 and the peripheral region 132 comprises at least one pressure sensor 121. The middle region 131 comprising at least one pressure sensor 121 means that the orthographic projection of the at least one pressure sensor 121 on the first surface 111 is within the middle region 131, so does the peripheral region 132.

When the product formed by the manufacturing process has defects or the manufacturing process is disturbed or even destroyed, the pressure in the middle region 131 and the pressure in the peripheral region 132 may be analyzed to determine whether the carrying performance of the wafer carrier is qualified. The carrying capacity of the wafer carrier is determined as unqualified, as long as the pressure in one of the regions does not meet the preset requirements. If the carrying capacity of the wafer carrier is unqualified, the fault cause can be quickly found based on the region that does not meet the preset requirements and then handled.

That is to say, the first surface 111 is divided into a plurality of smaller regions, and each region comprises at least one pressure sensor 121. The faulty region can be more accurately determined when there is a problem with the carrying capacity of the wafer carrier. Thus, the fault cause can be accurately found based on the faulty region. Therefore, the machine return time is shortened.

On the basis of dividing the first surface 111 into a middle region 131 and an peripheral region 132, the method of dividing the first surface 11 into a plurality of smaller regions further comprises: in a direction in which the middle region 131 faces the peripheral region 132, dividing the peripheral region 132 into a plurality of ring-shaped sub-regions sequentially surrounding one another, each ring-shaped sub-region and the middle region 131 comprising at least two pressure sensors 121. At the given ring width, the number of pressure sensors 121 in each ring-shaped sub-region is greater than or equal to the number of pressure sensors 121 in another ring-shaped sub-region surrounded by this ring-shaped sub-region.

In this embodiment, in order to improve the determination accuracy of the faulty region and reduce the difficulty in preparing the monitoring wafer, when the first surface 111 is a round surface and the diameter of the round surface is 300 mm, 33 pressure sensors are provided. In other embodiments, the diameter of the monitoring wafer may be 200 mm, and the number of pressure sensors may be set according to actual needs.

In this embodiment, by providing a pressure detection device on the substrate 11 of the monitoring wafer 1, the pressure detection device can obtain the pressure on the first surface 111 of the substrate 11 facing the wafer carrier 2. In this way, when the product formed by the manufacturing process has defects or the manufacturing process is disturbed or even destroyed, a determination may be made as to whether the adsorption capacity of the wafer carrier is qualified according to the pressure obtained by the pressure detection device. Thus, this avoids the removal of the wafer carrier before confirming whether a fault occurs, and further speeds up the return of the machine. In addition, the wafer carrier can be tested after reinstallation and machine maintenance to ensure that the wafer carrier has good carrying capacity.

Correspondingly, an embodiment of the present application further provides a fault location method, comprising: providing a wafer carrier and a monitoring wafer, the first surface of the monitoring wafer facing the wafer carrier and being fixed to the wafer carrier; subjecting the monitoring wafer to a preset process, and obtaining pressure data on the first surface during the preset process; and determining, based on the pressure data, whether the capacity of the wafer carrier for carrying the monitoring wafer is qualified.

The fault location method in this embodiment of the present application will be described in detail below with reference to the accompanying drawings.

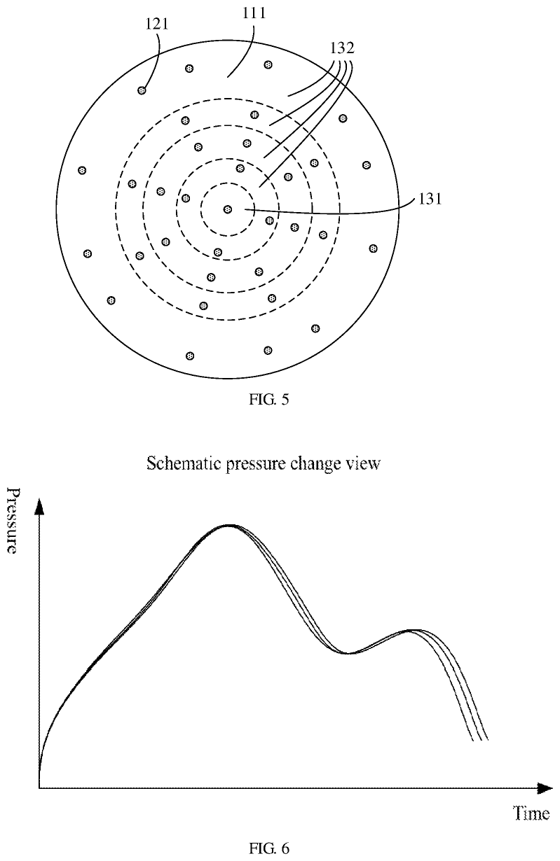

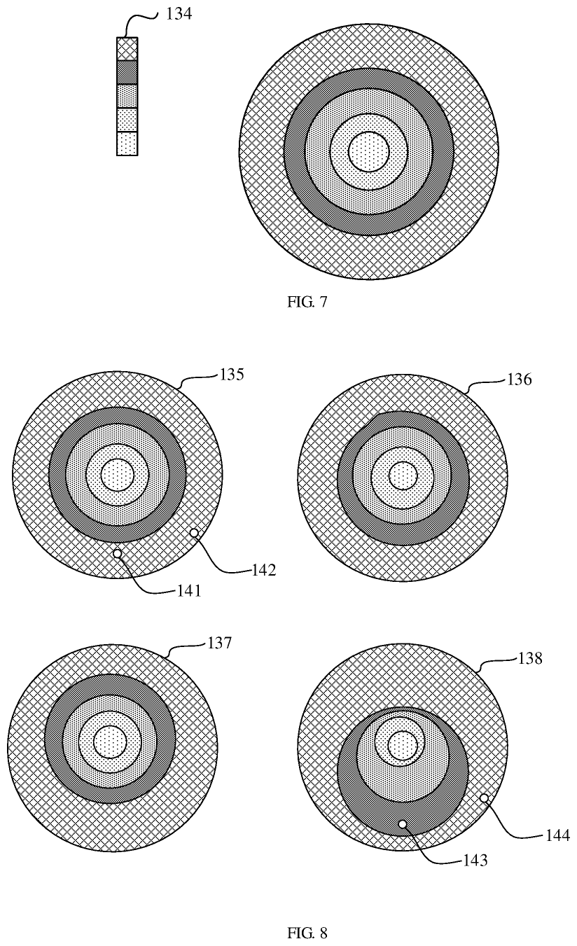

FIG. 6 is a schematic view of the change in pressure of the monitoring wafer according to an embodiment of the present application; and FIG. 7 is a schematic view of the distribution of pressure of the monitoring wafer according to an embodiment of the present application.

In this embodiment, the pressure detection device comprises a plurality of pressure sensors, and the pressure sensors obtain the pressure on the first surface in real time during the preset process. In this way, the pressure on the first surface at different points of time can be obtained. This is helpful to monitor whether there is a problem with the pressure on the first surface at any point of time.

Referring to FIG. 6, the schematic pressure change view comprises a plurality of pressure curves. The pressure curve can represent the pressure detected by a pressure sensor or the average of pressures in a region. In addition, when testing the carrying capacity of a plurality of wafer carriers, the pressure curve may be the average of pressures obtained for each monitoring wafer. The user may adjust the meaning of the pressure curve to meet different needs.

Since the pressure value of the pressure curve fluctuates over time, the user can intuitively determine whether the carrying capacity of the wafer carrier is abnormal according to the pressure at a certain point of time or the pressure difference at different points of time.

When the carrying capacity of the wafer carrier is found to be abnormal at a certain point of time, the pressure state of the wafer carrier at that point of time may be displayed. Referring to FIG. 7, the pressure detected by the pressure detection device is simulated by color using the pressure color table 134 as a standard. In this way, the user can intuitively determine the location of the abnormality, and then quickly find the fault cause based on the location of the abnormality and then handle it. Thus, the machine return time is shortened.

In this embodiment, the user may set the pressure curve to different meanings according to requirements, and may set different qualification conditions according to the different meanings of the pressure curve. For example, when the pressure detection device comprises a plurality of pressure sensors, the pressure curve may be set to represent the pressure detected by a pressure sensor, and as the qualification conditions, the pressure detected by any pressure sensor should be greater than a first preset value and the difference in pressure obtained by any two pressure sensors should be less than a second threshold value; when the first surface comprises a plurality of regions and each region comprises at least one pressure sensor, the pressure curve may be set to represent the average of pressures in a region, and as the qualification conditions, the average of pressures detected by the pressure sensors in any region should be greater than a third preset value and the difference in average of pressures detected by the pressure sensors in different regions should be less than a fourth preset value; and when a plurality of wafer carriers to be tested are detected, the pressure curve may be set to represent the average of pressures detected by a monitoring wafer, and as the qualification conditions, the average of pressures detected by the monitoring wafer should be greater than a fifth preset value.

When a plurality of chambers are used for the same manufacturing process to form products, it is usually needed to ensure that the products formed in different chambers have good consistency while ensuring that the products meet the requirements. That is, the products formed in different chambers should have a small difference. In order to ensure that the products formed in different chambers have good consistency, it is usually necessary to provide a reference chamber, and use the pressure distribution graph corresponding to the wafer carrier in the reference chamber as the reference standard. When there is a large deviation between the product formed in a chamber of a machine and the product formed in the reference chamber, the pressures detected by the monitoring wafers in different chambers are compared to determine whether the cause of the large deviation is the difference in the carrying capacity of the wafer carriers in different chambers.

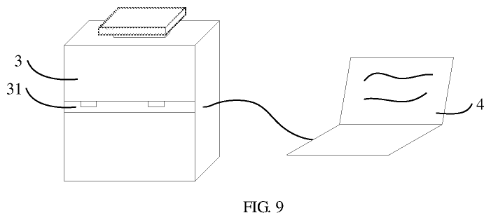

FIG. 8 is a schematic view of the distribution of pressure of the monitoring wafer according to another embodiment of the present application. The first pressure distribution graph 135 and the second pressure distribution graph 136 are from different chambers of a machine, and the third pressure distribution graph 137 and the fourth pressure distribution graph 138 are from different chambers of another machine. The first pressure distribution graph 135 is a pressure distribution graph of a wafer carrier with a qualified carrying capacity, and the fourth pressure distribution graph is a pressure distribution graph of a wafer carrier to be tested.

In this embodiment, when the difference between the pressure detected by the monitoring wafer corresponding to the wafer carrier to be tested and the pressure detected by the monitoring wafer corresponding to the wafer carrier with a qualified carrying capacity is less than a sixth preset value, the carrying capacity of the wafer carrier to be tested is qualified.

The pressure detected by the monitoring wafer may be the average of multiple pressures detected by the monitoring wafer; or the pressure at a specific position, for example, a first reference point 141 and a third reference point 143 at the same position on the pressure distribution graph; or the difference in pressure between two specific positions, for example the difference in pressure between the first reference point 141 and the second reference point 142 and the difference in pressure between the third reference point 143 and the fourth reference point 144.

In addition, in order to avoid large fluctuation in the pressure on the wafer carrier, during the preset process, when the difference in pressure detected by the monitoring wafer at different points of time is less than a seventh preset value, the carrying capacity of the wafer carrier is determined as qualified.

When the carrying capacity of the wafer carrier is determined as unqualified, the reason for the failure may be analyzed based on the pressure data that causes the failure. In addition, the service life of the wafer carrier may be analyzed based on the pressure data that causes the failure and the standard pressure data.

In this embodiment, the pressure on the first surface is monitored during the preset process. In this way, when a product has defects, a determination may be made as to whether the carrying capacity of the wafer carrier is qualified according to the pressure obtained by the pressure detection device. Thus, this avoids the removal of the wafer carrier before confirming whether a fault occurs. The maintenance efficiency is ensured.

Correspondingly, an embodiment of the present application further provides a monitoring system.

Referring to FIG. 9, the monitoring system comprises: at least one monitoring wafer; a wafer transfer box 3, configured to carry the monitoring wafer and obtain pressure data in the monitoring wafer; and an electronic device 4, connected to the wafer transfer box 3 and configured to obtain and analyze the pressure data.

The monitoring system in this embodiment of the present application will be described in detail below with reference to the accompanying drawings.

In this embodiment, the wafer transfer box 3 has a slot 31 used to carry the monitoring wafer. The wafer transfer box 3 has an adapter coil. The monitoring wafer has an induction coil and a power supply device connected to the induction coil. Mutual inductance is possible between the induction coil and the adapter coil. The wafer transfer box 3 can charge the power supply device in the monitoring wafer through an internal or external power source, the adapter coil and the induction coil.

In this embodiment, the size of the monitoring wafer is the same as a common wafer, and the wafer transfer box 3 is the same as the wafer transfer box used in daily production.

In this embodiment, the monitoring system can obtain pressure data in the monitoring wafer, and then can analyze the pressure data and draw icons that are convenient for problem analysis. This is helpful to quickly determine whether there is a fault and to find and handle the fault in time.

It may be understood by a person of ordinary skill in the art that the above-mentioned implementations are specific embodiments for realizing the present application, and in actual applications, various changes may be made to the form and details without departing from the spirit and scope of the present application. Those skilled in the art can make their own changes and modifications without departing from the spirit and scope of the present application. Therefore, the protection scope of the present application shall be subject to the scope defined by the claims.

1. A monitoring wafer, comprising:
a substrate, the substrate having a first surface that is configured to face a wafer carrier and fixed to the wafer carrier; and
a pressure detection device, located on the substrate and configured to obtain pressure on the first surface.

2. The monitoring wafer according to claim 1, wherein the substrate has a second surface opposite to the first surface, the substrate has a groove extending from the second surface to the first surface, and the pressure detection device is embedded in the groove; and
the monitoring wafer further comprises a protective layer located on the second surface and configured to seal the pressure detection device.

3. The monitoring wafer according to claim 2, further comprising: an adhesive layer, configured to adhere the substrate and the protective layer, a material for the adhesive layer comprising silicone resin adhesive.

4. The monitoring wafer according to claim 2, further comprising: an induction coil, connected to the pressure detection device and configured to supply power to the pressure detection device.

5. The monitoring wafer according to claim 4, further comprising: a power supply device, connected to the pressure detection device and the induction coil, respectively, and configured to receive charging of the induction coil and to supply power to the pressure detection device.

6. The monitoring wafer according to claim 4, further comprising: a processor, connected to the pressure detection device and configured to store pressure data obtained by the pressure detection device.

7. The monitoring wafer according to claim 6, wherein the processor is further configured to send the stored pressure data through the induction coil.

8. The monitoring wafer according to claim 1, wherein the pressure detection device comprises a signal amplifier and at least one pressure sensor, and the signal amplifier is configured to amplify the pressure obtained by the pressure sensor.

9. The monitoring wafer according to claim 8, wherein, in a direction in which the pressure sensor faces the first surface, a distance between a surface of the pressure sensor facing the first surface and the first surface is greater than or equal to 0.2 mm.

10. The monitoring wafer according to claim 1, wherein the pressure detection device comprises a plurality of pressure sensors; the first surface comprises a middle region and a peripheral region surrounding the middle region; and the middle region comprises at least one pressure sensor and the peripheral region comprises at least one pressure sensor.

11. The monitoring wafer according to claim 10, wherein in a direction in which the middle region faces the peripheral region, the peripheral region comprises a plurality of ring-shaped sub-regions sequentially surrounding one another, and each of the ring-shaped sub-regions comprises at least one pressure sensor.

12. The monitoring wafer according to claim 8, wherein the first surface is a round surface and the number of pressure sensors is 33.

13. A monitoring system, comprising:
at least one monitoring wafer according to claim 1;
a wafer transfer box, configured to carry the monitoring wafer and obtain pressure data in the monitoring wafer; and
an electronic device, connected to the wafer transfer box and configured to obtain and analyze the pressure data.

14. The monitoring system according to claim 13, wherein the monitoring wafer comprises an induction coil and a power supply device connected to the induction coil; the wafer transfer box comprises an adapter coil and mutual inductance is possible between the induction coil and the adapter coil; and the wafer transfer box charges the power supply device in the monitoring wafer through the adapter coil and the induction coil.

15. The monitoring system according to claim 14, wherein the wafer transfer box comprises an internal power source or external power source, and the wafer transfer box charges the power supply device in the monitoring wafer through the internal power source or external power source.

16. The monitoring wafer according to claim 3, further comprising: an induction coil, connected to the pressure detection device and configured to supply power to the pressure detection device.

17. The monitoring wafer according to claim 10, wherein the first surface is a round surface and the number of pressure sensors is 33.
